(19) United States
(12) Patent Application Publication
(10) Pub. No.: US 2007/0170599 A1
(43) Pub. Date: Jul. 26, 2007

(54) Flip-attached and underfilled stacked semiconductor devices

(76) Inventors: Masazumi Amagai, Ibaraki (JP); Masako Watanabe, Oita-city (JP)

Correspondence Address: TEXAS INSTRUMENTS INCORPORATED, P O BOX 655474, M/S 3999, DALLAS, TX, 75265, US

(21) Appl. No.: 11/337,985

(22) Filed: Jan. 24, 2006

(51) Int. Cl. H01L 23/48

(52) U.S. Cl. 257/783

(57) ABSTRACT

A tape for use as a carrier in semiconductor assembly, which has one or more base sheets 101 of polymeric, preferably thermoplastic, material having first (101a) and second (101b) surfaces. A polymeric adhesive film (102, 104) and a foil (103, 105) of different, preferably inert, material are attached to the base sheet on both the first and second surface sides; they thus provide a thickness (120) to the tape. A plurality of holes is formed through the thickness of the tape; the holes are preferably tapered with an angle between about 70° and 80° with the second tape surface. A reflow metal element (301), with a preferred diameter (302) about equal to the tape thickness, is held in each of the holes.

### FIELD OF THE INVENTION

The present invention is related in general to the field of electronic systems and semiconductor devices and more specifically to methods for fabricating flip-assembled, underfilled and stacked semiconductor devices.

### DESCRIPTION OF THE RELATED ART

When an integrated circuit (IC) chip is assembled on an insulating substrate with conducting lines, such as a printed circuit motherboard, by solder bump connections, the chip is spaced apart from the substrate by a gap; the solder bump interconnections extend across the gap. The IC chip is typically a semiconductor such as silicon, silicon germanium, or gallium arsenide, the substrate is usually made of ceramic or polymer-based materials such as FR-4. Consequently, there is a significant difference between the coefficients of thermal expansion (CTE) of the chip and the substrate; for instance, with silicon (about 2.5 ppm/° C.) as the semiconductor material and plastic FR-4 (about 25 ppm/° C.) as substrate material, the difference in CTE is about an order of magnitude. As a consequence of this CTE difference, thermomechanical stresses are created on the solder interconnections, especially in the regions of the joints, when the assembly is subjected to temperature cycling during device usage or reliability testing. These stresses tend to fatigue the joints and the bumps, resulting in cracks and eventual failure of the assembly. Any nascent microcrack will be aggravated in mechanical shock tests such as the drop test.

In order to distribute the mechanical stress and to strengthen the solder joints without affecting the electrical connection, the gap between the semiconductor chip and the substrate is customarily filled with a polymeric material, which encapsulates the bumps and fills any space in the gap. For example, in the well-known “C-4” process developed by the International Business Machines Corporation, polymeric material is used to fill any space in the gap between the silicon chip and the ceramic substrate.

The encapsulant is typically applied after the solder bumps have undergone the reflow process and formed the metallic joints for electrical contact between the IC chip and the substrate. A viscous polymeric, thermoset precursor, sometimes referred to as the “underfill”, is dispensed onto the substrate adjacent to the chip and is pulled into the gap by capillary forces. The precursor is then heated, polymerized and “cured” to form the encapsulant; after the curing process, the encapsulant is hard and cannot be softened again.

It is well known in the industry that the temperature cycling needed for the underfill curing process can create thermomechanical stress on its own, which may be detrimental to the chip and/or the solder interconnections. Additional stress is created when the assembly is cooled from the reflow temperature to ambient temperature. The stress created by these process steps may delaminate the solder joint, crack the passivation of the chip, or propagate fractures into the circuit structures. In general, the sensitivity to cracking of the layered structures of integrated circuits is increasing strongly with decreasing thickness of the various layers and increasing mechanical weakness of low dielectric constant insulators; any nascent microcrack will be magnified by mechanical shock tests such as the drop test.

### SUMMARY OF THE INVENTION

Applicants have recognized the need for a cost-effective assembly methodology, in which the stress-distributing benefits of the underfill material can be enjoyed without the deleterious side-effects of the underfilling process, resulting in enhanced device reliability. It is a technical advantage if the methodology provides an opportunity for device repair or re-working. The methodology should be coherent, low-cost, and flexible enough to be applied to different semiconductor product families, especially to stacked semiconductor device packages, and a wide spectrum of design and process variations. It is another technical advantage, if these innovations are accomplished while shortening production cycle time and increasing throughput.

One embodiment of the invention is a tape for use as a carrier, which consists of one or more base sheets of polymeric, preferably thermoplastic, material having first and second surfaces. A polymeric adhesive film and a foil of different material are attached to the base sheet on both the first and second surface sides; they thus provide a thickness to the tape. A plurality of holes is formed through the thickness of the tape; and a reflow metal element, with a preferred diameter about equal to the thickness, is placed in each of the holes.

Another embodiment of the invention is a semiconductor package made of a semiconductor device with an outline and plurality of contact pads and further an external part with a plurality of terminal pads. This part is spaced from the device, and the terminal pads are aligned with the device contact pads, respectively. A reflow element interconnects each of the contact pads with its respective terminal pad. Thermoplastic material fills the space between the device and the part; this material adheres to the device, the part and the reflow elements. Further, the material has an outline substantially in line with the outline of the device, and fills the space substantially without voids.

When the device is a semiconductor chip, the external part is a substrate suitable for flip-assembly of the chip. When the device is a semiconductor package encapsulating an assembled semiconductor chip, or a stack of packages, the external part is a board suitable for flip-attachment of the package. Due to the thermoplastic character of the filling material, the finished device can be reworked, when the temperature range for reflowing the reflow elements is reached.

Another embodiment of the invention is a method for assembling a semiconductor package, in which a semiconductor device with an outline and a plurality of contact pads is provided, further a tape as described above; the location of the holes, and thus the reflow metal elements in the holes, match the locations the contact pads. The foil is removed from the first tape surface side, whereby the polymeric adhesive film on the first tape side is exposed. The reflow elements of the tape are then placed in contact with the contact pads of the device while the first polymeric adhesive film on the first tape side holds the device in place. Thermal energy is supplied to the device and the tape sufficient to reflow the reflow elements and liquefy the thermoplastic base sheet. After cooling to ambient temperature, the tape is attached to the device substantially without leaving voids.

The process steps of the method may continue by providing an external part with a plurality of terminal pads in locations matching the locations of the reflow elements in the tape holes. The foil from the second surface side is removed, whereby the polymeric adhesive film on the second tape side is exposed. The reflow elements of the tape are then placed in contact with the terminal pads of the external part while the polymeric adhesive film on the second tape side holds the external part in place. Thermal energy is supplied to the device, the tape, and the external part sufficient to reflow the reflow elements and liquefy the thermoplastic base sheet. After cooling to ambient temperature, the tape is attached to the external part, while the workpiece is spaced apart from the external part and the space is filled substantially without leaving voids.

When the device is a semiconductor chip, the external part is a substrate suitable for flip-assembly of the chip. When the device is a semiconductor wafer containing a plurality of semiconductor chips, the external part is a substrate suitable for flip-assembly of the wafer. When the device is a semiconductor package, which encapsulates an assembled semiconductor chip, or a stack of packages, the external part is a board suitable for flip-attachment of the package or stack.

Embodiments of the present invention are related to flip-chip assemblies, ball grid array packages, chip-scale and chip-size packages, package-on-package and other devices intended for reflow attachment to substrates and other external parts. It is a technical advantage that the invention offers a methodology to reduce the thermomechanical stress between the semiconductor part of a device and a substrate of dissimilar thermal expansion coefficient while concurrently controlling essential assembly parameters such as spacing between the semiconductor part and the substrate, adhesion between the parts, and selection of the temperature ranges needed in the assembly process. Additional technical advantages derive from the fact that the devices made with the thermoplastic tape are reworkable. Further, the process flow is simplified since the conventional underfill process after the flip-assembly is eliminated.

The technical advantages represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1A shows schematically the cross section of a tape for use in semiconductor assembly in order to illustrate the structure of various insulating and adhesive layers according to an embodiment of the invention.

FIG. 1B shows schematically the cross section of a tape for use in semiconductor assembly in order to illustrate the structure of various insulating and adhesive layers according to another embodiment of the invention.

FIG. 2 shows schematically the cross section of the tape of FIG. 1A having a hole with tapered walls, formed to penetrate the tape thickness.

FIG. 3 is a cross section of the tape of FIG. 2 with an element of reflow metal positioned in the tape hole.

FIG. 4 shows a schematic cross section of the tape of FIG. 3 after removal of the outermost layer of the tape structure.

FIG. 5 is a schematic cross section illustrating a portion of the tape assembled on a workpiece.

FIG. 6 is a schematic cross section illustrating the tape portion of FIG. 5 after removal of a separator layer in order to expose the attached reflow element.

FIG. 7 is a schematic cross section illustrating a singulated tape and substrate unit with a reflow element, assembled on an external part.

FIG. 8 is a schematic cross section of a stack of semiconductor packages flip-attached onto an external board using the assembly tape of the invention.

### DETAILED DESCRIPTION OF THE PREFERRED EMBODIMENTS

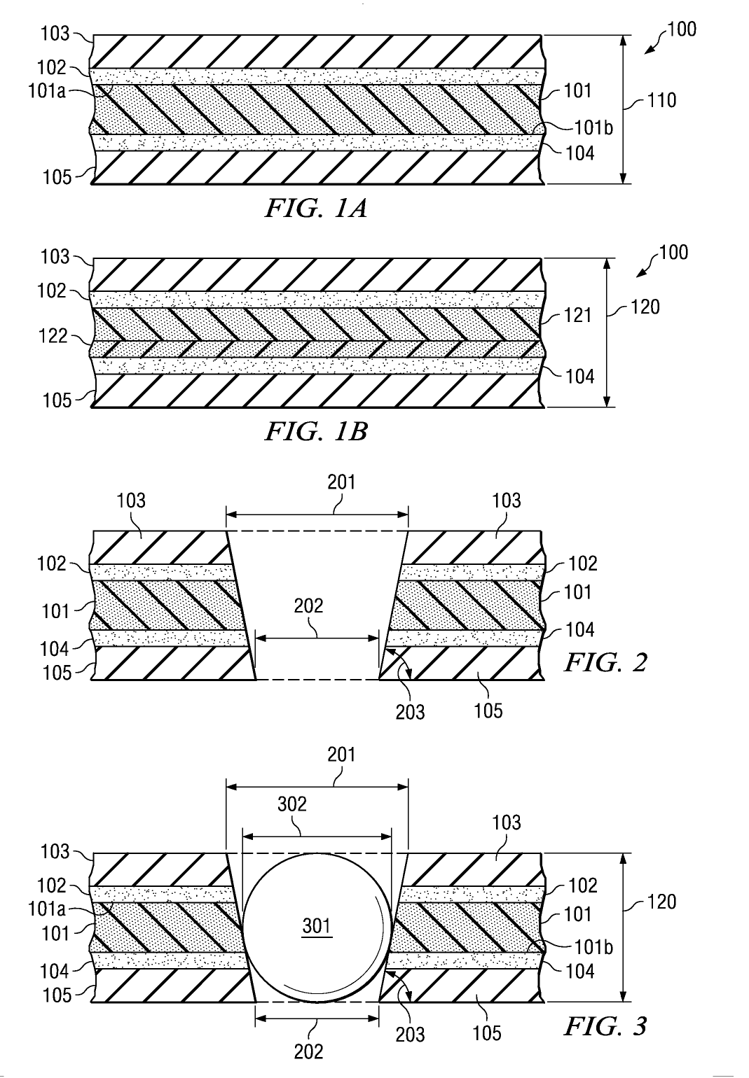

One embodiment of the invention is depicted in the schematic cross section of FIG. 1A as a tape, generally designated 100, for use as a carrier and specifically in semiconductor device assembly. Tape 100 consists of a base sheet 101 of polymeric, preferably thermoplastic material in the thickness range from about 25 to 450 μm; for some devices, the thickness may reach approximately 800 μm. Preferred thermoplastic base sheet materials include long-chain polyimides with acrylic resin or silicone resin, long-chain polyethylenes with acrylic resin, and long-chain polypropylenes with acrylic resin. The base sheet material is preferably selected so that it softens and enters the low viscosity or liquid phase in the same temperature range, which is needed for reflowing the reflow element embedded in the tape (see below). This temperature range includes, for example, the melting temperature of the solder selected for assembling the device. It is a technical advantage, when the base sheet is selected from thermoplastic materials, since the processes of liquefying and solidifying the thermoplastic material may be repeated numerous times without difficulty. Preferably, the coefficient of thermal expansion is selected between about 8 and 120 ppm, and the elasticity modulus between about 100 and 10000 MPa.

Base sheet 101 has a first surface 101a and a second surface 101b. Attached to the first surface 101a are a first polymeric adhesive film 102 followed by a first foil 103 of different material. In similar fashion, attached to the second surface 101b are a second polymeric adhesive film 104 followed by a second foil 105 of different material. The adhesive films 102 and 104 preferably include polymer materials such as epoxy, polyimide, or silicone, which have not only adhesive properties, but can also easily be peeled off; the adhesive films have a preferred thickness range from about 25 to 100 μm. The foils 103 and 105 comprise inert materials such as PVC and PET, and have a preferred thickness range from about 25 to 50 μm. Foils 103 and 105 are sometimes referred to as “separators”. Laminated tapes such as tape 100 are commercially available and can also be made to custom specification, for instance by the company Lintec, Japan.

The combination of the base sheet 101, the polymeric adhesive films 102 and 104, and the foils 103 and 105, provides a thickness 110 to tape 100. Thickness 110 is penetrated by a plurality of holes in tape 100 in order to provide space for reflow elements such as solder balls (see FIG. 3).

FIG. 1B illustrates a variation of the tape in FIG. 1A. The central base sheet is composed of two films 121 and 122, which are attached to each other over their whole area. Both films are made of polymeric, preferably thermoplastic silicone materials, and also include long-chain polyimides with acrylic resin or silicone resin, long-chain polyethylenes with acrylic resin, and long-chain polypropylenes with acrylic resin. The advantage of two films compared to only one film is improved adhesion to a solder ball inserted in a hole through the tape (see FIG. 3). Films 121 and 122 may have equal thicknesses or different thicknesses; the individual base film thickness is typically in the range from about 20 to 100 μm, but together, the base sheet thickness 120 of the pair may reach 450 μm or more.

The tape thickness 110 or 120 is determined by the size of the solder ball to be inserted into the tape holes; the ball size, in turn, is determined by the intended ball pitch. For example, 0.8 mm ball pitch uses 350 to 400 μm ball diameter; 0.5 mm ball pitch uses 250 to 300 μm ball diameter. When a product needs a different ball size, the tape thickness also needs to be changed.

When tape 100 is shaped as a sheet, a plurality of holes may be formed in tape 100. The position of these holes can be selected in any predetermined pattern. FIG. 2 shows one specific hole in more detail. The hole has a somewhat larger diameter 201 on one tape side and a smaller diameter 202 on the opposite tape side, resulting in a tapered contour. The diameters are selected so that a solder ball or cylinder can be reliably fitted in the hole. The tapered walls form an angle 203 at the small-diameter opening. The preferred angle 203 is between about 70° and 80°.

Among the techniques available for the opening processes are laser, mechanical drill, and mechanical punching. Experience has shown that the laser technique is superior to the drilling or punching techniques. The preferred laser method is excimer laser, because excimer laser has an accuracy of ±5 μm for defining the depth 110 and the diameters 201 and 202. The hole may be round or may have any other predetermined outline; the hole diameter may be same for all holes, or it may be different.

FIG. 3 shows one reflow metal element 301 in a hole of depth 110. Reflow element 301 has preferably a diameter 302 slightly less than the hole diameter 201, but larger than hole diameter 202. In this fashion, reflow element 301 is securely held in place in the hole and cannot be dislodged or fall out.

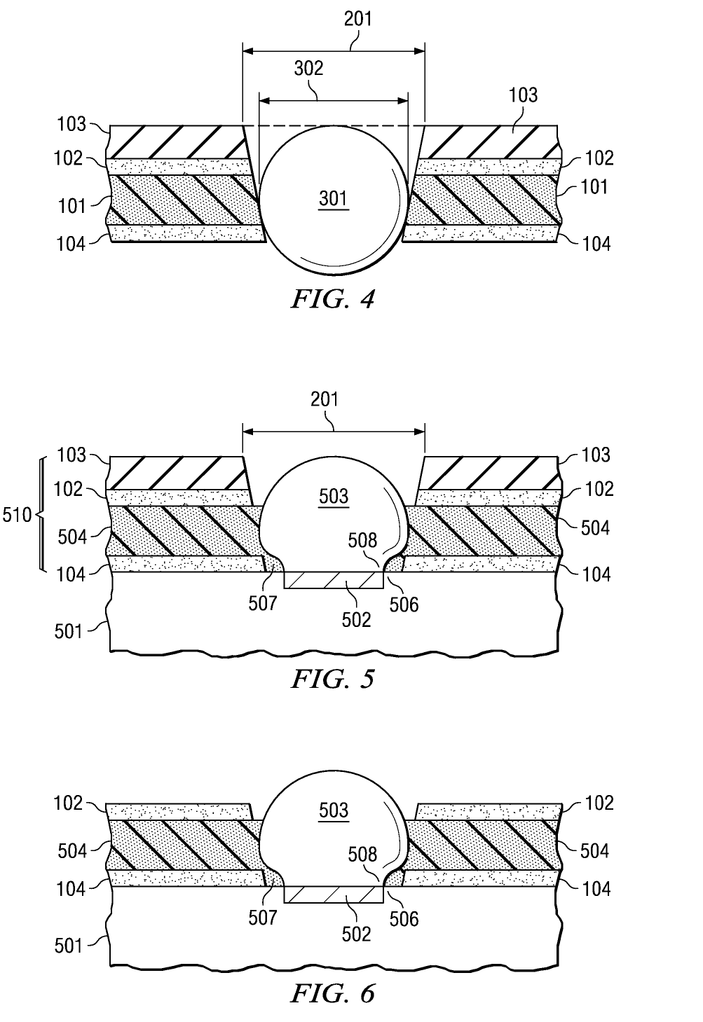

In order to highlight the technically superior features of tape 100, FIGS. 4 through 7 describe various process steps of assembly and device fabrication employing a semiconductor device, which has an outline and a plurality of contact pads. In embodiments for the semiconductor industry, the device is either a semiconductor wafer containing a plurality of semiconductor chips, or an individual semiconductor chip, or a semiconductor package, which encapsulates an assembled semiconductor chip on a substrate, or a stack of semiconductor packages. The tape is provided with the plurality of holes and inserted reflow elements in locations, which match the locations of the contact pads of the device.

The process flow starts with FIG. 4, wherein the separator 105 surrounding the narrow opening 202 of the tapered hole has been removed. Polymeric adhesive film 104 is now exposed. Reflow element 301 remains firmly in place, since it is in contact with polymeric base film 101. For many applications, the size of element 301 and the hole have been selected so that element 301 is slightly protruding from the hole at this stage of the process flow.

Next, a semiconductor device is provided. As an example for a specific device, a semiconductor wafer with a plurality of semiconductor chips facing upward is supplied. Each chip has a plurality of contact pads, facing upward. The tape is positioned over the wafer so that the locations of the plurality of reflow elements in the tape holes match the locations of the contact pads of the semiconductor chips on the wafer. The tape is lowered and each reflow element of the tape is brought into contact with its corresponding contact pad of the wafer. Preferably, polymeric adhesive film 104 is also in contact with the device, helping to stabilize the tape and the device.

As another example of a specific device, a molded entity, containing a plurality of semiconductor chips assembled (for instance, by attachment and wire bonding) on a substrate and encapsulated by molding compound, is provided. The substrate has a plurality of contact pads for each assembled chip, facing upward. The tape is positioned over the molded entity so that the locations of the plurality of reflow elements in the tape holes match the locations of the contact pads of the substrate of the molded entity. Preferably, polymeric adhesive film 104 is also in contact with the molded entity, helping to stabilize the tape and the entity.

The schematic cross section of FIG. 5 illustrates the next step of the fabrication process. Each reflow element 503 of the tape 510 is brought into contact with the respective contact pad 502 of the device 501 (it has been mentioned earlier that device 501 may be a semiconductor chip, a semiconductor package, or a stack of packages). This step may be facilitated by the polymeric adhesive film 104 holding device 501 in place. Thermal energy is then supplied to device 501 and tape 510 sufficient to reflow the reflow element 503 and liquefy the thermoplastic base sheet 504 (designated 101 in FIGS. 1A, 2, 3 and 4 before reflow), whereby tape 510 is attached to device 501.

In FIG. 5, the effect of the heating cycle is schematically indicated by two results: The reflow element 503 (for example, solder ball) has formed a joint 506 across the whole length of pad 605, while the remaining surface of the reflow element has been pulled by surface tension into an approximately spherical shape. The softened thermoplastic material 504 has filled the available space 507 around joint 506 and the reflowed metal neck 508. By selecting the appropriate heating temperature and time, the surrounding thermoplastic material is filling space 507 substantially without leaving voids.

When those embodiments, in which the device is an individual chip or an individual package, have been cooled to ambient temperature, the thermoplastic material has formed an outline, which is substantially in line with the outline of the workpiece. As defined herein, “in line” does not only include a straight line, continuing the outline of the workpiece; it also includes minor concave or convex contours. However, “in line” excludes the well-known meniscus, which is typically formed in conventional technology by dispensing thermoset underfill material. In the conventional fabrication process, the low-viscosity thermoset material is driven by surface tension to protrude outside the device contours to form the well-known meniscus.

In the next process step, the separator 103 surrounding the wide opening 201 of the tapered hole is removed, exposing the first polymeric adhesive film 102. The result is displayed in FIG. 6.

When device 501 is not an individual semiconductor chip, but a whole semiconductor wafer containing a plurality of semiconductor chips, it is preferred to execute, as the next process step after the stage shown in FIG. 6, the separation of the wafer, assembled with the tape, into discrete assembled devices. The preferred method of separation is sawing.

Similarly, when device 501 is not an individual semiconductor package, but a whole molded entity containing a plurality of assembled and encapsulated semiconductor chips, the next process step after the stage shown in FIG. 6 is preferably the separation of the entity, assembled with the tape, into discrete assembled packages. The preferred method of separation is sawing.

For the next process step, an external part is provided, which has a plurality of terminal pads in locations matching the locations of the reflow elements. As an example, the external part may be a substrate suitable for flip-assembly of the semiconductor chip, which has previously been attached to the tape. As another example, the external part may be a circuit board suitable for flip-assembly of the semiconductor package, which has previously been attached to the tape.

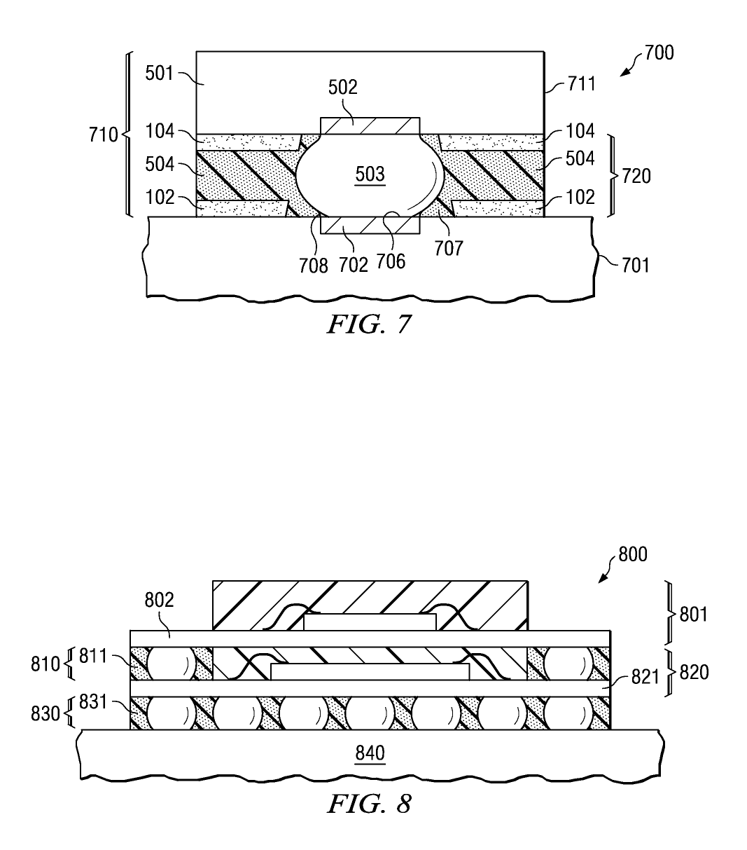

In FIG. 7, the external part is designated 701, and one of the plurality of terminal pads is designated 702. The device 501 with its contact pad 502 together with the attached remainder 720 of the tape and the reflow element form unit 710. Notice that unit 710 has been flipped relative to orientation in FIG. 6. Notice further that the side contours of unit 710 are shown as substantially straight contours 711; the straight contours are a consequence either of the singulation steps described above, or of the assembly using the tape with the thermoplastic base sheet.

The reflow element 503 of the tape, soldered to device contact pad 502, is placed in contact with the terminal pad 702 of the external part. In addition, the first polymeric adhesive film 102 may hold the external part 701 in place. Thermal energy is then supplied to the device 501, the tape 720, and the external part 701 sufficient to reflow the reflow element 503 and to liquefy the thermoplastic base sheet 504 of the tape 720. In FIG. 7, the effect of the heating cycle is schematically indicated by two results: The reflow element 503 has formed a joint 706 across the whole length of terminal pad 702; and the softened thermoplastic material 504 has filled the available space 707 around joint 706 and the reflowed metal neck 708. By selecting the appropriate heating temperature and time, the surrounding thermoplastic material is filling space 707 substantially without leaving voids. Further, after cooling to ambient temperature, the thermoplastic material 504 has approximately retained its outline 711, which is substantially in line with the outline 711 of the device.

As a result of the assembly process, the tape 720 and the workpiece 501 are attached to the external part 701, while the device 501 is spaced apart form the external part 701. The thermoplastic “underfill” material is in place to mitigate thermo-mechanical stress at the reflow interconnection and the solder joints due to its insignificant thermal shrinkage compared to conventional thermoset underfill materials. The finished product is generally designated 700 in FIG. 7.

For the assembly process steps described above, the materials for the polymeric adhesive films 102 and 104 are preferably selected so that they remain sticky in the temperature range from ambient temperature to about 300° C. and even higher, do not require a specific curing process, and have a decomposition temperature above about 300° C.

It is evident from the above description of the material selection and process flow that no flux is required for the metal reflow and soldering action, and any process-related stress on the metal reflow ball during the temperature cycles is minimized due to the continued presence of the thermoplastic polymer. Further, the thermoplastic material fills any available space substantially void-free. Experience has further shown that the choice of thermoplastic material and its continued presence during the fabrication process provides the semiconductor products with characteristics of reliability performances under use conditions as well as tests of temperature cycling, moisture sensitivity, and drop examinations, which are three to ten times higher than for products manufactured using prior art fabrication technologies.

The schematic FIG. 8 is an example of an embodiment, a semiconductor product generally designated 800, in which the device is a stack of semiconductor packages. A first package 801 has an extended substrate 802 with terminal pads on its surface opposite the attached chip. These terminal pads are attached by means of tape 810 to a second package 820, which has the extended substrate 821. Substrate 821 has two pluralities of contact pads: The plurality located on the chip-attachment surface serves the connection to package 801; the other plurality located on the opposite substrate surface serves the attachment to an external part 840. The attachment of the stack of two packages to the external part 840 is accomplished by tape 830. As an example, external part 840 may be a circuit wiring board.

In the reflow process step, the solder joint formation and the substantially void-free underfilling are performed concurrently. Notice that tapes 810 and 830 have outlines 811 and 831, respectively, which are substantially straight and in line with the outlines of the package substrates. This approximately straight outline is a consequence of the thermoplastic nature of the tape base material (for a package singulated from a molded entity it may also be created by the package separation process).

Stacks of packages are generally known to be sensitive to thermo-mechanical stress due to the distributed components of widely different coefficients of thermal expansion (silicon, metals, polymers, etc.). It is, therefore, a particular technical advantage of the invention to offer a stack structure and fabrication method based on thermoplastic underfill material, which reduces thermo-mechanical stress significantly by having a much smaller thermal shrinking than the thermoset materials of conventional art. With this advantage, it is easy for someone skilled in the art to construct composite devices such as displayed in FIG. 8 based on the concept and method of the invention, which have outstanding performance in reliability tests such as the drop test.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, for assemblies having interconnection elements with significantly higher or lower reflow temperatures, suitable base sheet thermoplastics and adhesives can be formulated by modifying the polymer chains of their materials. As another example, underfill materials of lower coefficients of thermal expansion can be formulated by adding inert (inorganic) fillers to the polymer base material. It is therefore intended that the appended claims encompass any such modifications and embodiments.

We claim:

1. A tape for use as a carrier comprising:
a base sheet of polymer material having first and second surfaces;
a polymeric adhesive film and a foil of different material attached to the base sheet on the first and on the second surface sides, providing a thickness to the tape;
a plurality of holes through the tape thickness; and
a reflow metal element seated in each of the holes.

2. The tape according to claim 1 wherein the polymer material of the base sheet includes a thermoplastic material selected from long-chain polyimides with acrylic resin or silicone resin, polyethylenes with acrylic resin, and polypropylenes with acrylic resin.

3. The tape according to claim 1 wherein the base sheet has a thickness between about 25 and 450 μm.

4. The tape according to claim 1 wherein the base sheet is composed of two polymer films attached to each other.

5. The tape according to claim 1 wherein the polymeric adhesive films have a thickness between about 25 and 100 μm and are made of polymers including epoxies and polyimides, and silicones.

6. The tape according to claim 1 wherein the foils of different materials have a thickness between about 10 and 50 μm and are made of inert materials including PVC and PET.

7. The tape according to claim 1 wherein the hole is tapered to form an angle between about 70° and 80° with the surface.

8. The tape according to claim 1 wherein the reflow metal elements have a diameter about equal to the tape thickness.

9. The tape according to claim 1 wherein the reflow metal elements are alloy solder balls.

10. The tape according to claim 1 wherein the reflow metal elements are alloy solder cylinders.

11. A semiconductor package, comprising:
a semiconductor device having an outline and plurality of contact pads;
an external part having a plurality of terminal pads, the part spaced from the device, and the terminal pads aligned with the device contact pads, respectively;
a reflow element interconnecting each of the contact pads with its respective terminal pad; and
polymeric material filling the space between the device and the part, the material adhering to the device, the part and the reflow elements, the material having an outline substantially in line with the outline of the device, and filling the space substantially without voids.

12. The package according to claim 11 wherein the device has at least one semiconductor chip, and the external part is a substrate suitable for flip-assembly of the at lest one chip.

13. The package according to claim 11 wherein the device has at least one assembled semiconductor chip, and the external part is a board suitable for flip-attachment of the at least one package.

14. The device according to claim 11 wherein the polymeric material is a thermo-plastic filling material operable to turn into a viscous fluid within approximately the same temperature range employed for reflowing the reflow elements.

15. A method for assembling a semiconductor package comprising the steps of:
providing a semiconductor device having an outline and a plurality of contact pads;
providing a tape having a base sheet of thermoplastic material and first and second surfaces; a polymeric adhesive film and a foil of different material attached to the base sheet on the first and on the second surface sides, providing a thickness to the tape; a plurality of holes through the tape thickness; a reflow metal element in each of the holes matching the locations of the semiconductor device contact pads;
removing the foil from the first tape surface side, exposing said polymeric adhesive film on the first tape side;
placing the reflow elements of the tape in contact with device contact pads;
supplying thermal energy to the device and the tape sufficient to reflow the reflow elements and liquefy the thermoplastic base sheet; and
cooling the device and the tape to ambient temperature, thus attaching the tape to the device.

16. The method according to claim 15 wherein the process step of contacting reflow elements and respective contact pads is facilitated by the adhesive film on the first tape side holding the workpiece in place.

17. The method according to claim 15 further comprising the steps of:
providing an external part having a plurality of terminal pads in locations matching the locations of the reflow elements in the tape holes;
removing the foil from the second surface side, exposing the polymeric adhesive film on the second tape side;
placing the reflow elements of the tape in contact with the terminal pads of the external part such that the polymeric adhesive film on the second tape side holds the external part in place;
supplying thermal energy to the device, the tape, and the external part sufficient to reflow the reflow elements and liquefy the thermoplastic base sheet; and
cooling the semiconductor device, the tape, and the external part to ambient temperature, thus attaching the tape to the external part, while spacing the device apart from the external part.

18. The method according to claim 17 wherein the liquefied thermoplastic base sheet fills the space between the workpiece and the external part substantially without voids.

19. The method according to claims 15 or 17 wherein the semiconductor device is a semiconductor wafer containing a plurality of semiconductor chips, and the external part is a substrate suitable for flip-assembly of the wafer.

20. The method according to claim 19 further comprising the step of separating the assembled wafer into discrete assembled chips, thereby singulating semiconductor devices.
